(19) United States
(12) Patent Application Publication
(10) Pub. No.: US 2008/0002839 A1
(43) Pub. Date: Jan. 3, 2008

(54) Smart equalizer

(75) Inventor: Eric D. Eng, Kirkland, WA (US)

Correspondence Address: WOODCOCK WASHBURN LLP (MICROSOFT CORPORATION), CIRA CENTRE, 12TH FLOOR, 2929 ARCH STREET, PHILADELPHIA, PA, 19104-2891, US

(73) Assignee: Microsoft Corporation, Redmond, WA (US)

(21) Appl. No.: 11/478,265

(22) Filed: Jun. 28, 2006

(51) Int. Cl. H03G 5/00

(52) U.S. Cl. 381/103

(57) ABSTRACT

An equalizer setting is stored for an audio file or an audio portion of an audio/video file and is then processed when the audio file is selected for playback. When a user operating a media device adjusts an equalizer setting of an audio file, the setting is associated with the audio file as part of the metadata of the audio file. Upon selection of the audio file, the metadata is examined to determine if an equalizer setting has been established for the audio file. The audio file is then played with the established equalizer setting. If an equalizer setting is not defined for the selected file, it may be played based upon a genre setting, which may be associated as part of the audio file's metadata, or based upon a distinguishing metadata attribute setting. A synchronization operation serves to provide consistent versions of the audio file on multiple devices.

### BACKGROUND

Users of desktop or portable devices, listening to and saving audio files on the devices and perhaps synchronizing two or more devices, often adjust the equalizer setting of an audio file while listening to the particular file. The equalizer setting is related to the audio frequency of an audio file. A user may prefer a different equalizer setting for each file or may prefer one specific setting for one type of music while another setting is more preferable for another type of music. Additionally, a preferred equalizer setting may exist for an audio portion of an audio/video (A/V) file, such as a music video or a movie.

Unfortunately, the equalizer setting, after being adjusted by the user, is not saved or associated with the audio file or the audio portion of the A/V file. Thus, when the audio file is selected to be played at a later time, the user must again adjust the equalizer setting to find the user's preferred setting. A user listening to audio files and adjusting the equalizer setting would prefer to save the adjusted setting of the audio file in order to eliminate future adjustments. Furthermore, it is desirable for the preferred equalizer setting to be associated with the audio file when a user synchronizes two or more music devices.

### SUMMARY

An equalizer setting of an audio file may be established by a user of a media device and applied to the audio file, allowing the audio file to later be processed and played with the desired equalizer setting. The application of the equalizer setting to the audio file may include storing the equalizer setting as part of the metadata of the audio file.

When an audio file is selected to be played, the audio file may be played based upon the equalizer setting. If the user has not established an equalizer setting for the selected audio file, it may instead be processed and played based upon the genre of the audio file. The genre of the audio file may be associated with the file as one of its metadata attributes. If an equalizer setting or genre metadata is not associated with the audio file, it may instead be processed and played based on any associated metadata attribute setting that distinguishes one file from another. The equalizer setting may be stored as metadata associated with the file, or as part of any data store on the playing computer or remote computer, accessed via wired or wireless connection.

A synchronization operation allows for the equalizer setting to be applied to the audio file on more than one device. The synchronization may automatically occur, based upon predefined settings, or the user may be presented with a prompt, in which case the synchronization may occur at the discretion of the user.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The foregoing summary and the following detailed description are better understood when read in conjunction with the appended drawings. Exemplary embodiments are shown in the drawings, however it is understood that the embodiments are not limited to the specific methods and instrumentalities depicted therein. In the drawings:

FIG. 1 is a block diagram representing an exemplary computing device;

FIG. 2 is a block diagram representing an equalization component;

FIG. 3 is a flow diagram illustrating one embodiment of a method of implementing an equalizer setting of an audio file; and

FIG. 4 is a flow diagram illustrating one embodiment of a method of applying an equalization property to an audio file.

### DETAILED DESCRIPTION

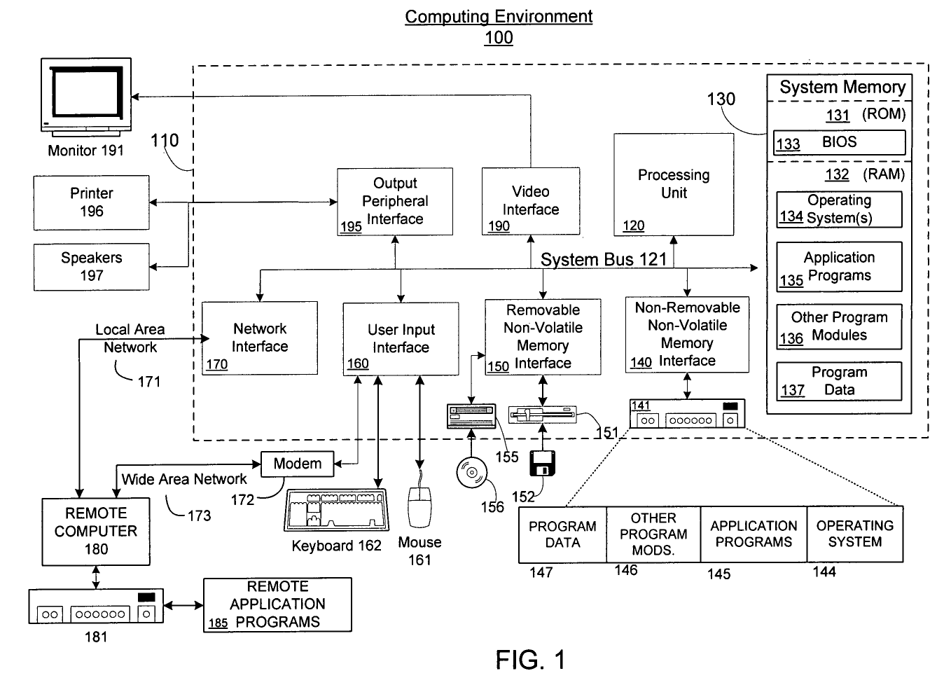

With reference to FIG. 1, an exemplary system for implementing the invention includes a general purpose computing device in the form of a computer 110. Components of computer 110 may include, but are not limited to, a processing unit 120, a system memory 130, and a system bus 121 that couples various system components including the system memory to the processing unit 120. The system bus 121 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus (also known as Mezzanine bus).

The computer 110 typically includes a variety of computer readable media. Computer readable media can be any available media that can be accessed by the computer 110 and includes both volatile and nonvolatile media, removable and non-removable media. By way of example, and not limitation, computer readable media may comprise computer storage media and communication media. Computer storage media includes both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by the computer 110. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of any of the above should also be included within the scope of computer readable media.

The system memory 130 includes computer storage media in the form of volatile and/or nonvolatile memory such as ROM 131 and RAM 132. A basic input/output system 133 (BIOS), containing the basic routines that help to transfer information between elements within the computer 110, such as during start-up, is typically stored in ROM 131. RAM 132 typically contains data and/or program modules that are immediately accessible to and/or presently being operated on by the processing unit 120. By way of example, and not limitation, FIG. 1 illustrates operating system 134, application programs 135, other program modules 136, and program data 137.

The computer 110 may also include other removable/non-removable, volatile/nonvolatile computer storage media. By way of example only, FIG. 1 illustrates a hard disk drive 141 that reads from or writes to non-removable, nonvolatile magnetic media, a magnetic disk drive 151 that reads from or writes to a removable, nonvolatile magnetic disk 152, and an optical disk drive 155 that reads from or writes to a removable, nonvolatile optical disk 156, such as a CD-ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 141 is typically connected to the system bus 121 through a non-removable memory interface such as an interface 140, and the magnetic disk drive 151 and the optical disk drive 155 are typically connected to the system bus 121 by a removable memory interface, such as an interface 150.

The drives and their associated computer storage media, discussed above and illustrated in FIG. 1, provide storage of computer readable instructions, data structures, components, program modules and other data for the computer 110. In FIG. 1, for example, the hard disk drive 141 is illustrated as storing operating system 144, application programs 145, other program modules 146, and program data 147. Note that these components can either be the same as or different from operating system 134, application programs 135, other program modules 136, and program data 137. Operating system 144, application programs 145, other program modules 146, and program data 147 are given different numbers here to illustrate that, at a minimum, they are different copies. A user may enter commands and information into the computer 110 through input devices such as a keyboard 162 and a pointing device 161, commonly referred to as a mouse, trackball or touch pad. Other input devices (not shown) may include a microphone, joystick, game pad, satellite dish, scanner, or the like. These and other input devices are often connected to the processing unit 120 through a user input interface 160 that is coupled to the system bus, but may be connected by other interface and bus structures, such as a parallel port, game port or a universal serial bus (USB). A monitor 191 or other type of display device is also connected to the system bus 121 via an interface, such as a video interface 190. In addition to the monitor, computers may also include other peripheral output devices such as speakers 197 and a printer 196, which may be connected through an output peripheral interface 195.

The computer 110 may operate in a networked environment using logical connections to one or more remote computers, such as a remote computer 180. The remote computer 180 may be a personal computer, a server, a router, a network PC, a peer device or other common network node, and typically includes many or all of the elements described above relative to the computer 110, although only a memory storage device 181 has been illustrated in FIG. 1. The logical connections depicted include a local area network (LAN) 171 and a wide area network (WAN) 173, but may also include other networks. Such networking environments are commonplace in offices, enterprise-wide computer networks, intranets and the Internet.

When used in a LAN networking environment, the computer 110 is connected to the LAN 171 through a network interface or adapter 170. When used in a WAN networking environment, the computer 110 typically includes a modem 172 or other means for establishing communications over the WAN 173, such as the Internet. The modem 172, which may be internal or external, may be connected to the system bus 121 via the user input interface 160, or other appropriate mechanism. In a networked environment, program modules depicted relative to the computer 110, or portions thereof, may be stored in the remote memory storage device. By way of example, and not limitation, FIG. 1 illustrates remote application programs 185 as residing on memory device 181. It will be appreciated that the network connections shown are exemplary and other means of establishing a communications link between the computers may be used.

All or portions of the methods described herein may be embodied in hardware, software, or a combination of both. When embodied in software, the methods, or certain aspects or portions thereof, may be embodied in the form of program code that when executed by a computing system cause the computing system to perform the methods. This program code may be stored on any computer-readable medium, as that term is defined above.

A user may utilize the computer 110 to save, access, and listen to various audio files or an audio portion of an audio/video (A/V) file. The audio files or audio portions may for example be saved in the system memory 130 or may be accessed from the optical disk drive 155 that reads from or writes to the removable, nonvolatile optical disk 156. The computer 110 utilized by the user may be a desktop personal computer, a mobile device, or an equalizer-enabled device, each operating to process audio files. Other devices capable of processing audio files may also be used.

Often the audio files may be of different genres, and the user may prefer to play audio files of a particular genre with a particular equalizer setting. Or the user may prefer different equalizer settings for each audio file, regardless of the genre. For example, the user may prefer to listen to classical audio files with a classical genre equalizer setting or may prefer a unique equalizer setting for each classical audio file. Numerous possibilities of equalizer settings may exist for each user.

The user may adjust, through various means of the computer 110, the equalizer setting associated with an audio file. Controls on the keyboard 162 or the mouse 161 may be manipulated to obtain a preferred setting or to sample multiple settings. Additionally, an indication of a current equalizer setting and the adjustment of the equalizer setting may be displayed to the user on the monitor 191 through an interface, such as a graphical user interface.

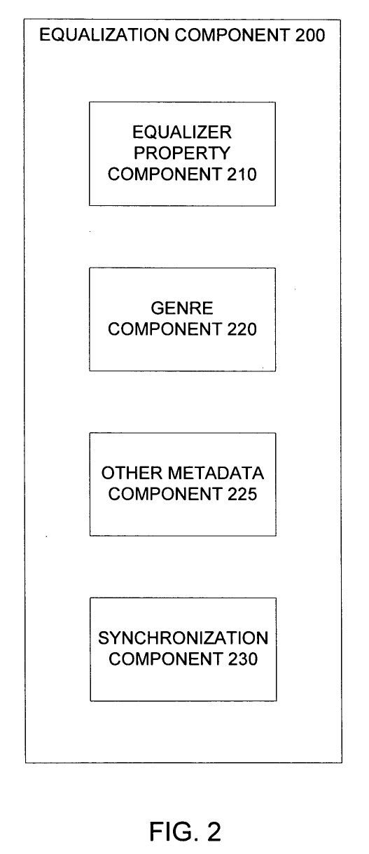

FIG. 2 illustrates a block diagram of an example equalization component 200, which may operate to play an audio file associated with an equalizer setting and apply an equalizer setting to an audio file as established and adjusted by a user. The equalization component 200 includes several means, devices, software, and/or hardware for performing functions, including an equalizer property component 210, a genre component 220, an other metadata component 225, and a synchronization component 230.

The equalizer property component 210 operates to store an equalizer setting of an audio file with the audio file. The equalizer setting, which may be adjusted by the user when listening to the audio file, may be stored as a metadata attribute of the audio file. The equalization component 200 may further operate to determine, upon selection of the audio file by a user, if an equalizer setting is established for the particular audio file. Thus, for example, when the user selects an audio file in which the user previously established an equalizer setting, the equalization component 200 functions to determine, from the audio file's metadata, if an equalizer setting exists for the selected audio file. If an equalizer setting is established for the audio file, then the equalization component 200 operates to process and play the audio file with the established equalizer setting.

If an equalizer setting for a selected audio file is not defined, then the equalizer property component 210 may accordingly communicate this information to the genre component 220. The genre component 220 may operate to play the selected audio file based upon the genre of the selected audio file. In order for the genre component 220 to perform such functions, the genre of the audio file may be associated with the audio file as, for example, a metadata attribute of the audio file. If the genre component 220 receives an indication from the equalizer property component 210 that an equalizer setting is not associated with the audio file selected by the user to be played, then the audio file may be played with an equalizer setting according to the genre. The preferred equalizer settings of different genres may be specified by the user or by an outside source. The genre attribute, for example rock, pop, and/or jazz, may be set or updated by the user, may be set when the content of the audio file or audio portion of the A/V file is created, for example when the audio file is encoded, or may be set or updated by an application. If an equalizer setting or genre metadata is not associated with the audio file, it may instead be processed and played based on any associated metadata attribute setting that distinguishes one audio file or portion of an audio file from another file or file portion. Other metadata attributes may be used to set the equalizer setting, for example, “GenreID”, “type”, or “mood.”

If an equalizer setting or genre metadata is not associated with the audio file, it may instead be processed and played, by for example the other metadata component 225, based on any associated metadata attribute setting that distinguishes one file from another. The equalizer setting may be stored as metadata associated with the file or as part of any data store on the equalizer-enabled device.

The synchronization component 230 may operate to synchronize the equalizer setting of audio files stored on multiple devices. If an audio file is played with an equalizer setting as desired and established by the user of the computer 110, the user may wish to synchronize the equalizer setting with other devices also containing the audio file, or copy the file and the setting to other devices, so that the desired setting is applied on each of the user's devices. For example, if the user adjusts or creates the equalizer setting of an audio file while listening to the audio file on an equalizer-enabled devices such as a mobile device, the synchronization component 230 of the equalization component 200 provides an option to the user to apply the equalizer setting as stored on the mobile device to another equalizer-enabled device of the user, such as a desktop personal computer. If the user indicates a desire to synchronize the devices, the indication is received by the synchronization component 230, and the synchronization component 230 performs a synchronization operation. The synchronization operation may include updating or revising the metadata of the audio file, as saved on the other device, to include the new equalizer setting.

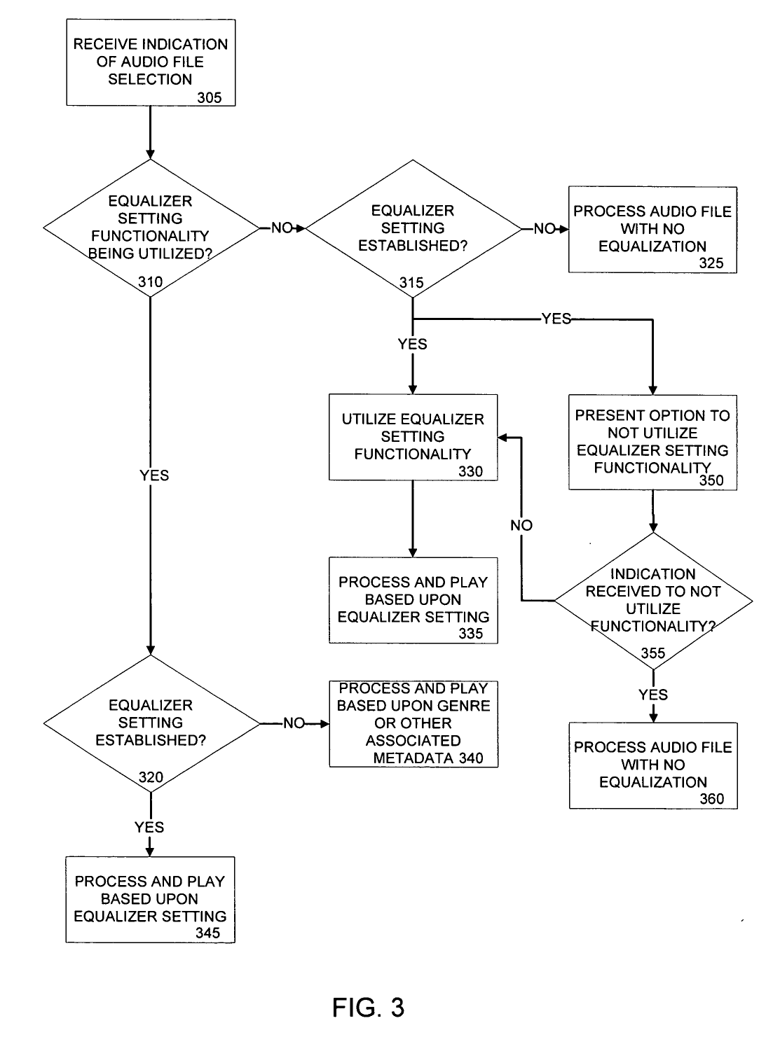

When an equalizer setting is associated with an audio file or an audio portion of an A/V file, such as a movie file, the equalizer setting may be implemented when the audio file or audio portion is selected to be played by a user. FIG. 3 illustrates an example method of implementing an equalizer setting of an audio file.

At 305, an indication that an audio file is selected by a user operating a computer 110, such as a desktop personal computer or a mobile device, is received. The indication may be received by the equalizer property component 210 of the equalization component 200. At 310, a determination is made to establish if the user is utilizing an equalizer setting functionality. This determination may be made by the equalizer property component 210. The user, for example, may not be aware of the equalizer setting functionality of the computer 110 or may not wish to utilize the functionality at a particular time and/or for a particular audio file.

Regardless of whether the user who selected the audio file is utilizing the equalizer setting functionality, at 315 and at 320, a subsequent determination is made to confirm whether an equalizer setting is established for the selected audio file. This determination may also be made by the equalizer property component 210 or the other metadata component 225, for example.

If the equalizer setting is not being utilized as determined at 310, following 315, if the determination performed by the equalizer property component 210 indicates that an equalizer setting for the audio file is not established, then at 325, the audio file is processed and played with no equalization. Thus, if the equalizer setting functionality is not being utilized and an equalizer setting has not previously been assigned, the audio file will not incorporate an equalizer setting.

Alternatively, following the determination at 315 that an equalizer setting is established for the selected audio file, at 330 the equalizer setting functionality is utilized. At 335, the audio file is processed and played based upon the equalizer setting. The processing and playing operations may be performed by the equalizer property component 210. Therefore, if an equalizer setting of an audio file is established, the audio file may accordingly be processed and played with the established setting even if the equalizer setting functionality is not initially being utilized by the user. Thus, the user will be presented with the audio file based upon a previously determined and preferred setting.

Alternatively, rather than automatically utilizing the equalizer setting functionality, at 350, the user may be presented with an option to listen to the audio file without the established equalizer setting. Such an option may be desirable if, for example, an additional user is handling the computer 110 of the original user who established the setting and the additional user prefers different equalizer settings than the original user. The optional selection may be displayed on the monitor 191 of the computer 110 and may include instructions to be followed by the user if the user desires to listen to the audio file without the established equalizer setting. At 355, following the presentation of the option to not utilize the equalizer setting functionality, an analysis is done, for example by the equalization component 200, in order to determine if an indication is received indicating the user's desire to not utilize the functionality. At 360, if such an indication is received, then the audio file is processed and played without the equalizer setting. If no indication is received, then at 330 the equalizer setting functionality is utilized.

If the equalizer setting is being utilized as determined at 310, following the determination at 320 of whether an equalizer setting for the selected audio file is defined, the method may proceed to 340 or 345. At 340, if the equalizer setting is not defined, then the selected audio file is processed and played with an equalization defined by the genre or other associated metadata of the audio file, for example. The equalizer property component 210, upon the determination that the audio file is not associated with an equalizer setting and that the equalizer setting functionality is being utilized, may communicate this determination to the genre component 220 or to the other metadata component 225. The genre component 220 will subsequently operate to process and play the selected audio file based upon the audio file's associated genre. If a genre setting does not exist, the other metadata component 220 will operate to process and play the selected audio file based upon an appropriate metadata attribute setting.

If, as determined at 320, that an equalizer setting for the audio file is established, then at 345, the audio file is processed and played, by the equalizer property component 210, with the established equalizer setting. Thus, if the user is utilizing the equalizer setting functionality of the computer 110, then the audio file will be played with either a defined equalizer setting or another setting associated with the audio file, such as genre, for example. The defined equalizer setting and the genre may be associated with the audio file as part of the audio file's metadata.

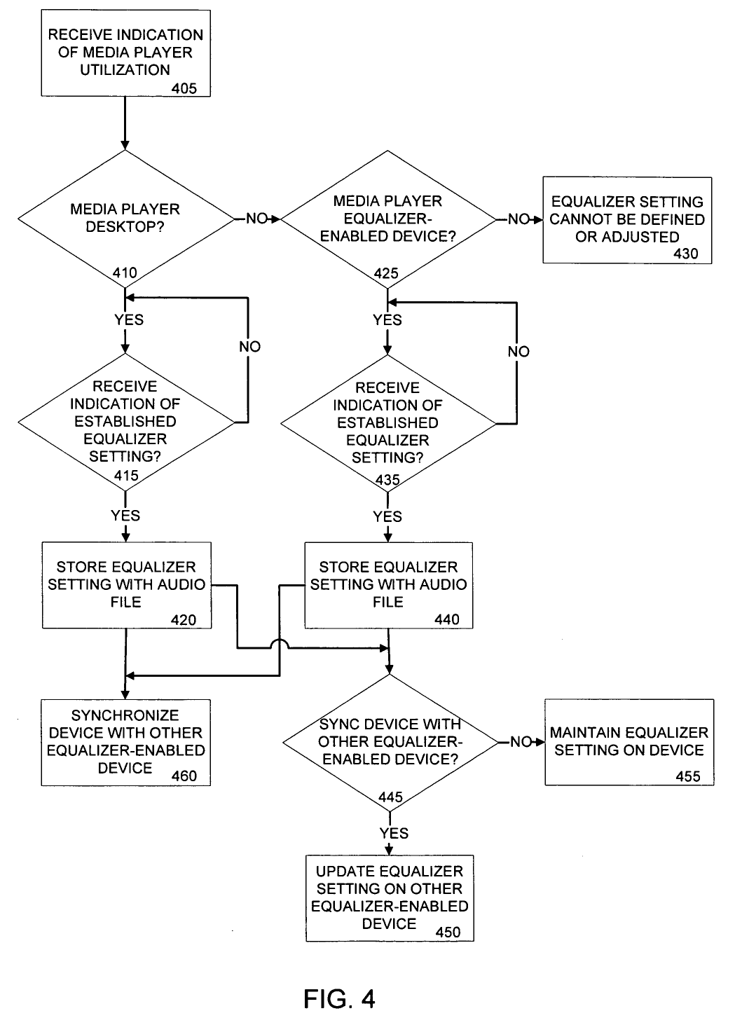

An example method of applying an equalization property to an audio file is described with relation to the flow diagram of FIG. 4. Such a method may be implemented when a user of a device, such as the computer 110 which may be for example a desktop personal computer or a portable media player, wishes to associate an equalizer setting with an audio file or an audio portion of a file.

The application of an equalization property to an audio file begins at 405, where the equalization component 200 receives an indication that a media player, which may be the computer 110, is being utilized. At 410, a determination is made to ascertain if the media player is a desktop media player. If the media player is a desktop media player, then at 415, a determination is made to ascertain if an indication is received, by the equalizer property component 210 for example, indicating that a user has established an equalizer setting for an audio file. When the indication is received that an equalizer setting has been established, at 420, the equalizer setting is associated and stored with the audio file. The association may include incorporating the equalizer setting as part of the metadata of the audio file. This incorporation enables the equalization component 200, for example, to recall and apply the equalizer setting of the audio file when the audio file is next selected to be played by the user.

At 425, if it had been determined at 410 that the media player being utilized is not a desktop media player, a subsequent determination is made to establish if the media player is an equalizer-enabled device. The equalizer-enabled device may be, for example, a mobile device, an automotive computer, or a set-top box. If, as determined by the equalization component 200 for example, the media player is neither a desktop media player nor an equalizer-enabled device, then, at 430, the application method ends without an equalizer setting being applied or adjusted.

Alternatively, at 435, upon determination that the operating media player is an equalizer-enabled device, a determination may be made to confirm if an indication of an established equalizer setting has been received, similar to 415. At 440, similar to 420, when an indication is received that an equalizer setting has been established for the selected audio file, the equalizer setting is associated and stored with the audio file, for example, as part of the metadata of the audio file. Again, the incorporation of the equalizer setting as part of the audio file's metadata enables the equalization component 200, and in particular the equalizer property component 210, for example, to recall and apply the equalizer setting of the audio file when the audio file is next selected to be played by the user.

At 445, following 420 and 440, the equalization component 200, and in particular the synchronization component 230 of the equalization component 200, may provide an option to the user to synchronize the device with another equalizer-enabled device. The option may be provided to the user through a user interface, and the option may be selected by the user through manipulation of the keyboard 162 or mouse 161 of the computer 110, for example. The synchronization option may be desirable to a user wishing to maintain the same equalizer settings of audio files on multiple devices. For example, a user of a desktop media player may wish to synchronize the desktop media player with an equalizer-enabled mobile device. If, at 445, an indication is received by the synchronization component 230 that the user wishes to synchronize the device with another device capable of handling the equalizer setting functionality, then at 450 the synchronization component 230 performs a synchronization operation. The synchronization operation desirably results in the equalizer setting being updated as part of the metadata of the audio file stored on the other equalizer-enabled device, for example. If the audio file was not on the other device, then the audio file, and its metadata or metadata attribute, which now include the audio file's equalizer setting, is transferred and stored on the other device. At 455, if the synchronization component 230 does not receive a synchronization indication from 445, then the equalizer setting is not updated to the other device and remains part of the metadata of the audio file on the device.

Optionally, the user may desire that synchronization automatically occur rather than being presented with and responding to a synchronization option. Thus, at 460, following 420 and 440, the synchronization component 230 performs a synchronization operation. The synchronization operation desirably results in the equalizer setting being updated as part of the metadata of the audio file stored on the other device, for example. If the audio file was not on the other device, then the audio file, and its metadata or metadata attribute which now include the audio file's equalizer setting, is transferred and stored on the other device. The automatic synchronization option may be specified by the user or the device, for example.

The incorporation of the equalizer setting as part of the audio file's metadata or as part of any data store on the equalizer-enabled device, as is executed at 420 and 440 after the equalizer setting is established on either a desktop media player or another equalizer-enabled device, may be performed upon completion of the processing of the audio file. Alternatively, the equalizer setting incorporation as part of the audio file's metadata may be periodically executed during the processing of the audio file. In such an embodiment, the equalizer setting is saved in the event of a processing error or accidental shutdown of the device. The periodic execution may be performed at time intervals specified by the user of the device. Or the time intervals may instead be established or overridden by the device.

As can be appreciated, the disclosed embodiments may be implemented as a whole or in part in one or more computing systems or devices. FIG. 1 illustrates the functional components of one example of a computing system 100 in which aspects may be embodied or practiced. As used herein, the terms “computing system,” “computer system,” and “computer” refer to any machine, system or device that comprises a processor capable of executing or otherwise processing program code and/or data. Examples of computing systems include, without any intended limitation, personal computers (PCs), minicomputers, mainframe computers, thin clients, network PCs, servers, workstations, laptop computers, hand-held computers, programmable consumer electronics, multimedia consoles, game consoles, satellite receivers, set-top boxes, automated teller machines, arcade games, mobile telephones, personal digital assistants (PDAs) and any other processor-based system or machine. The terms “program code” and “code” refer to any set of instructions that are executed or otherwise processed by a processor. Program code and/or data can be implemented in the form of routines, programs, objects, modules, data structures and the like that perform particular functions.

It is noted that the forgoing examples have been provided merely for the purpose of explanation and are in no way to be construed as limiting. While the inventions have been described with reference to various embodiments, it is understood that the words which have been used herein are words of description and illustration, rather than words of limitation. Further, although the embodiments have been described herein with reference to particular means, materials, and examples, the embodiments are not intended to be limited to the particulars disclosed herein; rather, the embodiments extend to all functionally equivalent structure, methods and uses, such as are within the scope of the appended claims.

What is claimed:

1. A method of implementing an equalizer setting of an audio file, the method comprising:
determining if an equalizer setting for the audio file is established;
upon determination that the equalizer setting is established, playing the audio file based upon the equalizer setting; and
upon determination that the equalizer setting is not established, one of (i) playing the audio file based upon a genre of the audio file, (ii) playing the audio file based upon an associated metadata attribute setting, and (iii) playing the audio file without equalization.

2. The method of claim 1, further comprising:
determining if an equalizer setting functionality is operating.

3. The method of claim 2, wherein playing the audio file based upon a genre of the audio file comprises upon determination that an equalizer setting functionality is operating and that the equalizer setting is not established, playing the audio file based upon a genre of the audio file.

4. The method of claim 2, wherein playing the audio file based upon an associated metadata attribute setting comprises upon determination that an equalizer setting functionality is operating and that the equalizer setting is not established, playing the audio file based upon an associated metadata attribute setting.

5. The method of claim 2, wherein playing the audio file without equalization comprises upon determination that an equalizer setting functionality is not operating and that the equalizer setting is not established, playing the audio file without equalization.

6. The method of claim 1, wherein playing the audio file based upon a genre of the audio file comprises:
determining the genre of the audio file based upon a predetermined genre setting associated with the audio file;
obtaining the equalizer setting of the genre of the audio file; and
playing the audio file with the obtained equalizer setting.

7. The method of claim 1, wherein playing the audio file based upon an associated metadata attribute setting comprises:
obtaining the associated metadata attribute setting of the audio file; and
playing the audio file with the obtained associated attribute setting.

8. A method of applying an equalizer setting to an audio file, the method comprising:
receiving an indication that the equalizer setting of the audio file is established; and
storing the equalizer setting of the audio file as metadata with the audio file or as part of a data store.

9. The method of claim 8, further comprising:
upon receipt of an indication to play the audio file, obtaining the stored equalizer setting of the audio file; and
playing the audio file with the stored equalizer setting.

10. The method of claim 8, further comprising:
determining that a device playing the audio files is one of (i) a desktop computer or (ii) an equalizer-enabled device;
upon determination that the device playing the audio file is a desktop computer or an equalizer-enabled device, providing an opportunity to synchronize the desktop computer or the equalizer-enabled device with another device.

11. The method of claim 10, further comprising:
receiving an indication to synchronize the desktop computer or the equalizer-enabled device with the other device; and
synchronizing the desktop computer or the equalizer-enabled device with the other device.

12. The method of claim 8, wherein receiving an indication that the equalizer setting of the audio file is established comprises receiving an indication that the equalizer setting is changed from a previous equalizer setting.

13. The method of claim 8, further comprising:
processing the audio file;
wherein storing the equalizer setting of the audio file as metadata with the audio file or as part of a data store comprises storing the equalizer setting upon completion of the processing of the audio file.

14. The method of claim 8, further comprising:
processing the audio file;
wherein storing the equalizer setting of the audio file as metadata with the audio file or as part of a data store comprises storing the equalizer setting at periodic time intervals during the processing of the audio file.

15. An equalization component for applying an equalizer setting to an audio file being processed on a device being accessed by a user, comprising:
an equalizer property component for storing a preferred equalizer setting of the audio file with the audio file;
a genre component for storing a genre equalizer setting of an audio file with the audio file based upon the genre of the audio file; and
a metadata component for storing a distinguishing metadata attribute setting of the audio file;
wherein the preferred equalizer setting overrides the genre equalizer setting.

16. The equalization component of claim 15, wherein the equalizer property component further operates to determine if a selected audio file is associated with a preferred equalizer setting.

17. The equalization component of claim 15, further comprising:
a synchronization component for synchronizing two devices with the preferred equalizer setting of the audio file.

18. The equalization component of claim 17, wherein the synchronization component performs a periodic synchronization during a processing of the audio file.

19. The equalization component of claim 15, wherein the equalizer property component communicates an indication to at least one of the genre component and the metadata component if a preferred equalizer setting of an audio file is not stored with the audio file.

20. The equalization component of claim 15, wherein the preferred equalizer setting, the genre equalizer setting, and the distinguishing metadata attribute setting are stored as part of metadata of the audio file or are stored by a data storage method.
